(19) United States
(12) Patent Application Publication
(10) Pub. No.: US 2024/0429232 A1
(43) Pub. Date: Dec. 26, 2024

(54) INTEGRATED CIRCUIT INCLUDING A CAPACITIVE ELEMENT, AND CORRESPONDING MANUFACTURING METHOD

(71) Applicant: STMicroelectronics International N.V., Geneva (CH)

(72) Inventors: Abderrezak MARZAKI, Cabries (FR); Alexandre VILLARET, Eybens (FR)

(73) Assignee: STMicroelectronics International N.V., Geneva (CH)

(21) Appl. No.: 18/747,571

(22) Filed: Jun. 19, 2024

(30) Foreign Application Priority Data
Jun. 26, 2023 (FR) 2306637

(51) Int. Cl. H01L 27/06; H01L 21/8234; H01L 29/49; H01L 29/51; H01L 29/66; H01L 29/78

(52) U.S. Cl. CPC H01L 27/0629; H01L 21/823437; H01L 28/40; H01L 29/513; H01L 29/66477; H01L 29/78; H01L 29/4966; H01L 29/517

(57) ABSTRACT

An integrated circuit includes a substrate having a front face. A capacitive element includes, over a surface at the front face, a stack made of: a first conductive armature, a dielectric interface region over the first conductive armature, and a second conductive armature over the dielectric interface region. The first conductive armature includes a gate metal layer located over a layer of a material with a high dielectric constant.

### PRIORITY CLAIM

This application claims the priority benefit of French Application for U.S. Pat. No. 2,306,637, filed on Jun. 26, 2023, the content of which is hereby incorporated by reference in its entirety to the maximum extent allowable by law.

### TECHNICAL FIELD

Embodiments and implementations relate to integrated circuits and, in particular, to integrated capacitive element technologies, in particular in integrated circuits including transistors featuring “high-K/metal gate” type gate structures.

### BACKGROUND

Conventionally, a transistor gate structure is referred to by the phase “high-K/metal gate” when the gate dielectric of the transistor includes a material with a high dielectric constant K, which will be herein referred to as “high-K”, and when the gate conductive region of the transistor includes a so-called “gate” metal layer (commonly referred to as a “metal gate”).

Also conventionally, the term high-K dielectric refers to materials of the semiconductor industry having a higher dielectric constant K that that of silicon dioxide.

The gate metal typically allows for setting the output work of the gate, the gate further including a volume of another gate material configured to receive a contact and a polarization (typically the material referred to polycrystalline silicon).

Finally, a “high-K/metal gate” type gate structure is found in particular, yet not necessarily, in semiconductor-on-insulator (SOI) type circuits.

In general, there is a need for profiting, in the integrated circuit, from capacitive elements that are linear and adapted to operate in an accumulation regime and in an inversion regime (i.e., having a substantially constant capacitive value for polarizations at positive and negative voltages).

Furthermore, it is desirable that the manufacture of capacitive elements is or could be co-integrated with the manufacture of other elements of the circuit, such as Metal Oxide Semiconductor (MOS) transistors (i.e., this manufacture of the capacitor being carried out “for free” during the same manufacturing steps used for making the various other included circuit elements).

### SUMMARY

The embodiments and implementations suggested hereinafter allow manufacturing Metal-Insulator-Metal (MIM) type capacitive elements and therefore linear in accumulation and in inversion, and carried out in a co-integrated way for free or at a lesser cost in a method for manufacturing “high-K/metal gate” type transistors by reusing the gate metal for the manufacture of an armature (electrode or plate) of the capacitive element, and the gate conductive material for the other armature (electrode or plate) of the capacitive element.

In this respect, according to one aspect, an integrated circuit is provided including a region having a front face, for example a region of a semiconductor substrate, and at least one capacitive element including, over a surface at the front face, a stack of a first conductive armature including a gate metal layer located over a layer of a material with a high dielectric constant “high-K” for a dielectric interface region over the first conductive armature, and of a second conductive armature over the dielectric region.

According to one embodiment, the gate metal layer includes a titanium nitride composition.

According to one embodiment, the high-K dielectric layer includes a hafnium or zirconium oxide and/or silicide composition (for example, a composition of hafnium oxide, or of hafnium silicide, or of hafnium oxysilicide, or a composition of zirconium oxide, or of zirconium silicide, or of zirconium oxysilicide).

According to one embodiment, the second conductive armature includes a polycrystalline silicon composition.

According to one embodiment, the first conductive armature includes an encapsulation polycrystalline silicon layer wrapping the gate metal layer.

According to one embodiment, the first conductive armature includes a polycrystalline silicon local region in contact with the gate metal layer, and configured for ohmic coupling with a metallic contact.

According to one embodiment, the integrated circuit further includes at least one Metal Oxide Semiconductor (MOS) transistor, including a gate region comprising a stack of a formation identical to said second conductive armature over a formation of layers identical to said first conductive armature.

According to one embodiment, the integrated circuit further includes at least one high-voltage MOS transistor, including a gate dielectric region comprising a formation identical to said dielectric interface region over a surface at the front face.

According to one embodiment, said region having a front face is: a shallow isolation trench region; or a region of a semiconductor thin film; or a region of a volume of a semiconductor substrate.

According to one embodiment, said at least one capacitive element further includes, between said surface at the front face and said layer of a material with a high dielectric constant “high-K”, at least one gate dielectric layer.

According to another aspect, a method is provided for making at least one capacitive element in an integrated circuit, including, starting from a front face of a region, for example a region of a semiconductor substrate, manufacturing a first conductive armature including a step of forming a layer of a material with a high dielectric constant “high-K” over a surface of said front face and a step of forming a gate metal layer over the high-K material layer; manufacturing a dielectric interface stacked over the first conductive armature, and manufacturing a second conductive armature stacked over the dielectric region.

According to one embodiment, the step of forming the gate metal layer includes forming a titanium nitride composition.

According to one implementation, the step of the high-K dielectric layer includes forming a hafnium or zirconium oxide and/or silicide composition.

According to one implementation, the manufacture of the second conductive armature includes forming a polycrystalline silicon composition.

According to one implementation, the manufacture of the first conductive armature further includes a step of forming an encapsulation polycrystalline silicon layer wrapping the gate metal layer.

According to one implementation, the manufacture of the first conductive armature further includes a step of forming a polycrystalline silicon local region in contact with the gate metal layer and configured to make an ohmic coupling with a metallic contact.

According to one implementation, the method further includes, concomitantly with making of at least one MOS transistor including a gate region, the manufacture of the gate region comprising a manufacture of layers identical to said manufacture of the first conductive armature, and a manufacture identical to said manufacture of the second conductive armature over said formation of layers.

According to one implementation, the method further includes, concomitantly with making of at least one high-voltage MOS transistor including a manufacture of a gate dielectric region identical to said manufacture of the dielectric interface region over a surface at the front face.

According to one implementation, said region having a front face is: a shallow isolation trench region; or a region of a semiconductor thin film; or a region of a volume of a semiconductor substrate.

According to one implementation, the manufacture of the first conductive armature further includes a step of forming at least one gate dielectric layer, between said surface at the front face and said layer of a material with a high dielectric constant that is “high-K”.

### BRIEF DESCRIPTION OF THE DRAWINGS

Other advantages and features of the invention will become apparent upon examining the detailed description of non-limiting embodiments and implementations, and from the accompanying drawings, in which figures:

FIGS. 1A-1D illustrate a first example of a method for forming a capacitive element;

FIGS. 2A-2D illustrates a second example of the method for forming a capacitive element; and

FIGS. 3, 4 and 5 illustrate embodiments of the capacitive element obtained by the manufacturing methods of FIGS. 1A-1D and FIGS. 2A-2D.

### DETAILED DESCRIPTION

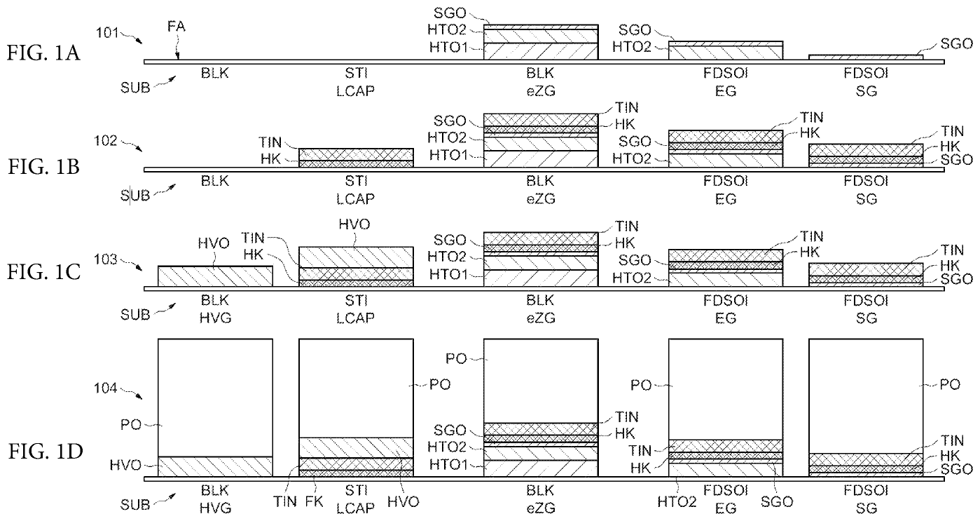

FIGS. 1A-1D illustrate a first example of a method for forming a capacitive element LCAP in an integrated circuit.

Advantageously, steps 101, 102, 103, 104 of the method for forming the capacitive element LCAP are compatible with steps of manufacturing gate structures of MOS transistors, including a “high-K/metal gate” type structure having common voltage range characteristics.

Indeed, steps 101, 102, 103, 104 of forming the capacitive element LCAP as shown in FIGS. 1A-1D allow manufacturing, for example simultaneously on a common substrate SUB, a low-voltage gate structure SGT of transistors suitable for logical operations, a medium-voltage gate structure EG of transistors suitable for signal communications, and a high-voltage gate structure eZG of transistors suitable for the generation and transmission of high-voltages.

The formations of steps 101-104 are carried out starting from a front face FA of a semiconductor substrate SUB.

For example, the low-voltage gate structures SG and the medium-voltage gate structures EG are formed in regions of the substrate SUB of the fully-depleted silicon-on-insulator (FDSOI) type.

For example, the high-voltage gate structures eZG may be formed over a region of the bulk volume BLK of the substrate SUB.

Advantageously, the capacitive element is formed at the front face FA, over a shallow isolation region (STI), typically formed at the beginning of the production line by a shallow trench isolation technique allowing laterally delimiting active regions (typically the channel regions of the transistors) of devices made in and over the substrate SUB.

In step 101, three thicknesses of gate dielectrics, typically silicon oxide, for the high-voltage eZG, medium-voltage EG and low-voltage SG gate structures, have been deposited, the thicknesses decreasing in that order (corresponding to the voltage ranges of the transistors).

In this respect, for example, a first dielectric layer HTO1 has been formed over the front face FA in the high-voltage region eZG; then a second dielectric layer HTO2 over the first dielectric layer of the high-voltage region and over the front face FA in the medium-voltage region EG; then a low-voltage dielectric interface layer SGO in particular in the high-voltage eZG, medium-voltage EG and low-voltage SG regions, and possibly over the entirety of the front face FA. It is considered that the thickness of the dielectric interface layer SGO is negligible compared to the thickness of the first layer HTO1 and to the thickness of the second layer HTO2.

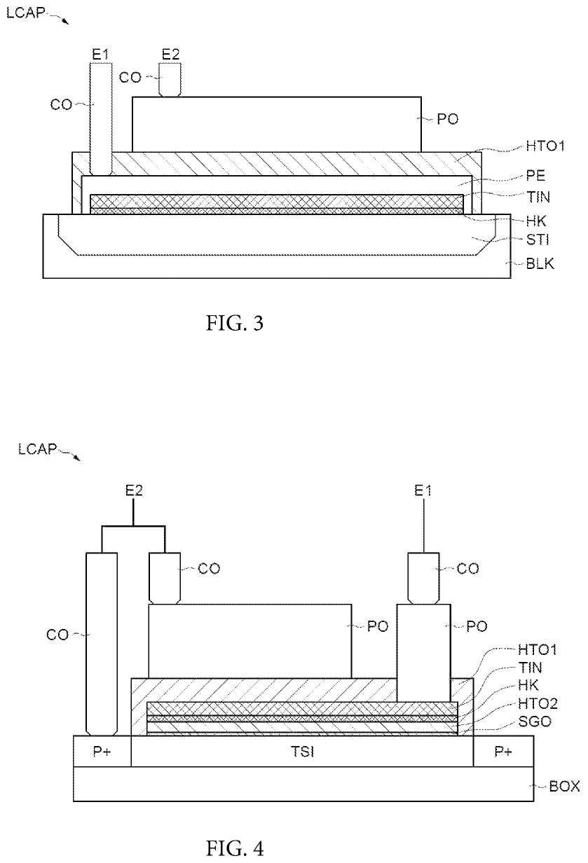

In step 102, the “high-K/gate metal” type structures have been formed over the dielectric layers HTO1, HTO2, SGO of the gate structures SG, EG, eZG; and, simultaneously, a first conductive armature (plate or electrode) TIN (reference E1—FIGS. 3 to 5) of the capacitive element LCAP has been manufactured.

On the one hand, step 102 includes, in this respect, forming a layer of a material with a high dielectric constant “high-K” over the dielectric layers HTO1, HTO2, SGO made in step 101 of the gate structures SG, EG, eZG; and over the front face FA in the shallow isolation region which accommodates the capacitive element LCAP. For example, the high-K dielectric layer HK includes a hafnium oxide and/or silicide composition or a zirconium oxide and/or silicide composition.

On the other hand, step 102 includes, in this respect, forming a gate metal layer TIN over the high-K material layer HK. For example, the gate metal layer TIN includes a titanium nitride (TiN) composition.

In a particular implementation, corresponding for example to FIG. 3, the step of forming the gate metal layer TIN may be accompanied with forming an associated encapsulation polycrystalline silicon conductive layer PE, intended to wrap (i.e., cover) the top and the sides of the gate metal layer TIN.

The gate metal layer TIN, and the possible encapsulation polycrystalline silicon layer, form the first conductive armature of the capacitive element LCAP, at the front face FA over the shallow isolation trench STI.

In step 103, the dielectric interface HVO of the capacitive element LCAP is manufactured, over the first conductive armature TIN, for example through an additional step of forming a dielectric layer, such as that made of silicon oxide, stacked over the gate metal layer TIN made for example, of titanium nitride.

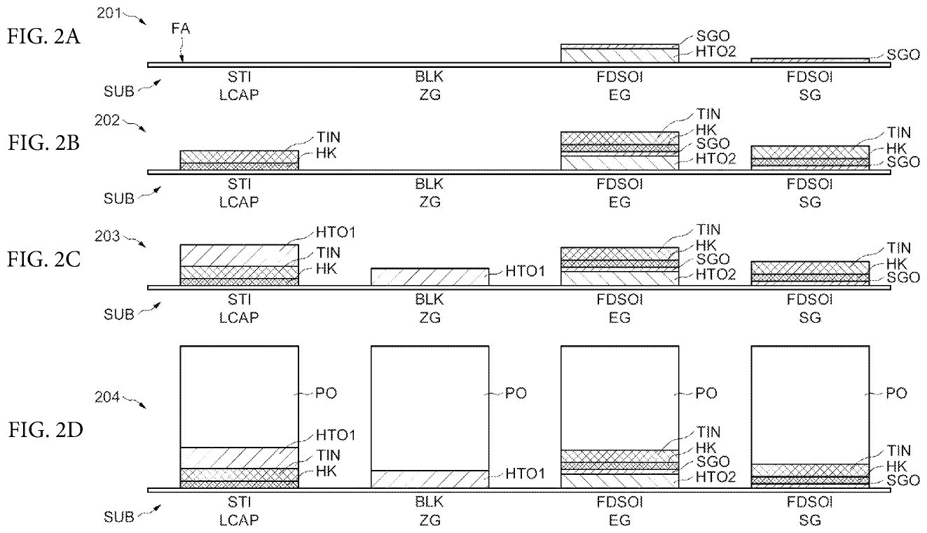

It should be noted that this first implementation provides for an additional step of forming a dielectric layer for making the capacitive element LCAP. This has an additional manufacturing cost, but also has the advantage of not modifying the stack of layers HTO1, HTO2, HK, TIN of the high-voltage gate structure eZG (in particular compared to the implementation described with reference to FIGS. 2A-2D) and also the possibility of making a second type of high-voltage gate structure HVG for free.

Indeed, it is possible to provide in step 103 for the manufacture of a gate dielectric layer HVO adapted to a second high-voltage range, yet possibly different from the high-voltage range of the gate structure eZG. Indeed, it is possible to form the layer HVO with a thickness different from the thickness of the stack HTO1, HTO2, independently of the constructions of the medium-voltage gate structures EG (HTO2).

The second type of high-voltage transistor HVF does not include a “high-K/gate metal” structure but this is not necessarily detrimental to high-voltage applications, and is for example formed over a volume of the semiconductor substrate BLK.

In step 104, the second conductive armature (electrode or plate) PO (reference E2—FIGS. 3 to 5) is manufactured, stacked over the dielectric region HVO, concomitantly with the manufacture of the gate conductive regions HV, eZG, EG, SG of the transistors, typically formed by a polycrystalline silicon composition PO.

Thus, conventional “high-K/gate metal” transistors SG, EG, have been manufactured (i.e., transistors whose gate dielectric layers include a high-K dielectric layer and have thicknesses adapted to different voltage ranges, and whose gate conductive regions include a metallic layer TIN at the interface of the high-K dielectric HK).

During the same steps, it has been possible to form a Metal-Insulator-Metal (MIM) type capacitive element LCAP, where the first metallic armature is made by the gate metal TIN, where the insulator is made by the dielectric layer HVO, and where the second conductive armature PO is made by the polycrystalline silicon of the gates PO. Thus, the capacitive element LCAP is linear in accumulation and in inversion.

Furthermore, it is possible to freely manufacture a conventional second high-voltage transistor HVG without the “high-K/gate metal” structure.

FIGS. 2A-2D illustrates a second example of the method for forming a capacitive element LCAP of an integrated circuit.

Herein again, steps 201, 202, 203, 204 of forming the capacitive element LCAP are advantageously compatible with steps of manufacturing, perhaps simultaneously on a common substrate, low-voltage SG, medium-voltage EG and high-voltage ZG gate structures of MOS transistors.

In fact, the second exemplary implementation of the method 201-204 enables a totally free co-integration of the method for manufacturing the capacitive element LCAP, into a method for manufacturing gate structures SG, EG, ZG of a MOS transistor.

In this second example, the low-voltage gate structures SG are identical to those of the first example, whereas the constructions of the medium-voltage EG and high-voltage ZG gate structures are slightly modified.

Step 201 corresponds to the previously-described step 101, but wherein the first dielectric layer HTO1 has not been formed over the front face FA in the high-voltage region eZG.

Thus, only the second dielectric layer HTO2 over the front face FA in the medium-voltage region EG, then the dielectric interface layer SGO, have been formed.

Step 202 corresponds to step 102, in which the “high-K HK/gate metal TIN” type structures are formed over the dielectric layers HTO2, SGO of the gate structures SG, EG; allowing manufacturing the first conductive armature (plate or electrode) TIN (reference E1—FIGS. 3 to 5) simultaneously with the capacitive element LCAP, in the same way as described before with reference to FIGS. 1A-1D.

It should be noted, in particular, that the stack of the high-K dielectric HK and gate metal TIN layers is not made in the portion receiving the high-voltage gate ZG.

In step 203, the first dielectric layer HTO1 is then formed in the portion of the high-voltage gate ZG, and simultaneously over the first conductive armature TIN of the capacitive element LCAP, thereby forming the dielectric interface layer HTO1 of the capacitive element LCAP.

Step 204 corresponds to step 104, in which the second conductive armature (plate or electrode) PO, stacked over the dielectric region HVO, is manufactured concomitantly with the manufacture of the gate conductive region ZG, EG, SG of the transistors, typically with a polycrystalline silicon composition PO.

It should be noted that this second implementation does not provide for an additional step of forming a dielectric layer for making the capacitive element LCAP. Thus, the second exemplary implementation of the method 201-204 is advantageously fully co-integrated with the manufacture of the transistors SG, EG, ZG, and therefore totally free.

Indeed, the step of forming the first gate dielectric layer HTO1 of the high-voltage transistor ZG has advantageously been “shifted” after the steps of forming the high-K dielectric layer and the gate metal layer TIN. Consequently, the high-voltage gate structure ZG does not profit from the “high-K/gate metal” structure but, as mentioned before, this does not affect the high-voltage ranges.

Furthermore, since the first dielectric layer HTO1 does not define any thickness other than that of the gate dielectric of the high-voltage structure ZG, it is possible to provide, in step 203, for the manufacture of the first layer HTO1 with a desired different thickness independently of the constructions of the other gate structures.

Thus, conventional low-voltage SG and medium-voltage EG “high-K/gate metal” transistors; a conventional high-voltage transistor HVG without the “high-K/gate metal” structure; and the “MIM”-type capacitive element LCAP have been manufactured; where the first metallic armature is made by the gate metal TIN, where the insulator is made by the first dielectric layer HTO1, and where the second conductive armature PO is made by the polycrystalline silicon of the gates PO.

FIGS. 3, 4 and 5 illustrate embodiments of the capacitive element LCAP thus obtained by the manufacturing methods described with reference to FIGS. 1A-1D and FIGS. 2A-2D.

Thus, in the three examples, the capacitive element LCAP includes, over a surface at the front face FA, a stack of a first conductive armature E1 including a gate metal layer TIN located over a layer of a material with a high dielectric constant “high-K” HK, of a dielectric interface region HTO1, HVO over the first conductive armature E1, and of a second conductive armature E2 over the dielectric region HTO1, HVO.

The gate metal layer TIN may include a titanium nitride composition. The high-K dielectric layer HK may include a hafnium oxide and/or silicide composition, or a zirconium oxide and/or silicide composition. The second conductive armature E2 may include a polycrystalline silicon composition PO.

FIG. 3 illustrates the embodiment wherein the first conductive armature E1 includes an encapsulation polycrystalline silicon layer PE, wrapping the gate metal layer TIN.

The formation of the encapsulation polycrystalline silicon layer PE may be automatically provided for with the formation of the gate metal layer TIN of the transistors SG, EG, ZG, and does not generate any additional cost dedicated to the formation of the capacitive element LCAP.

For example, the encapsulation polycrystalline silicon layer PE may be provided to protect the gate metal TIN (for example from oxidation), and be intended to be etched later on, for example.

That being so, in the capacitive element LCAP, the encapsulation polycrystalline silicon layer PE advantageously allows connecting a contact CO, usually made of copper or of aluminum, through an ohmic coupling with a conventional silicidation of an exposed surface of the polycrystalline silicon PE.

Indeed, the thickness of the gate metal layer TIN is fine compared to the thicknesses of the polycrystalline silicon volumes usually connected by the contacts.

For example, the orders of magnitude of said thicknesses (vertically in the direction of the drawing) may amount to 3.5 nm (nanometers) for the gate metal TIN, 12 nm for the encapsulation polycrystalline silicon PE, and 48 nm for the polycrystalline silicon PO of the second armature E2

Moreover, in this embodiment and in the examples of methods described with reference to FIGS. 1 and 2, the capacitive element LCAP is located over a surface at the front face FA, of a dielectric volume STI. For example, the dielectric volume STI consists of a shallow isolation trench construction.

This allows profiting from a linear capacitive value (i.e., substantially constant) in the inversion and accumulation regimes.

FIG. 4 illustrates another embodiment, wherein the encapsulation polycrystalline silicon layer PE is absent. In this case, to connect the first armature E1 of the capacitive element LCAP, it is possible to provide for forming a local region made of a polycrystalline silicon PO in an opening formed in the dielectric interface HTO1 up to the first armature E1, during step 104/204 of manufacturing the second armature E2.

Thus, the polycrystalline silicon local region PO allows connecting the contact CO through an ohmic coupling with a conventional silicidation of a surface of the region PO.

This alternative where the encapsulation polycrystalline silicon layer PE is absent and including the local region PO of polycrystalline silicon is perfectly applicable if the capacitive element LCAP is located over a surface at the front faced FA, of a dielectric volume STI, as described with reference to FIG. 3, in particular in order to profit from the linearity of the capacitive value in the inversion and accumulation regimes.

Moreover, in this other embodiment, the first armature TIN of the capacitive element LCAP is formed on the one hand above the second gate dielectric layer HTO2 (for example made in the manner obtained at steps 103/203 for the medium-voltage gate structure EG) and, on the other hand, opposite a region of the substrate including a semiconductor thin film TSI over a buried insulating volume BOX, i.e. of the semiconductor-on-insulator (SOI) type substrate.

Thus, a Metal Oxide Semiconductor (MOS) type second capacitive interface is made between the first armature TIN and the semiconductor film TSI. This additional “MOS” capacitive element may add to the “MIM”-type capacitive element LCAP, through a parallel connection of the thin film TSI with the polycrystalline silicon PO of the second armature E2. The semiconductor thin film TSI may conventionally be connected by contacts CO on highly P+ doped regions with the same type of dopants as the film.

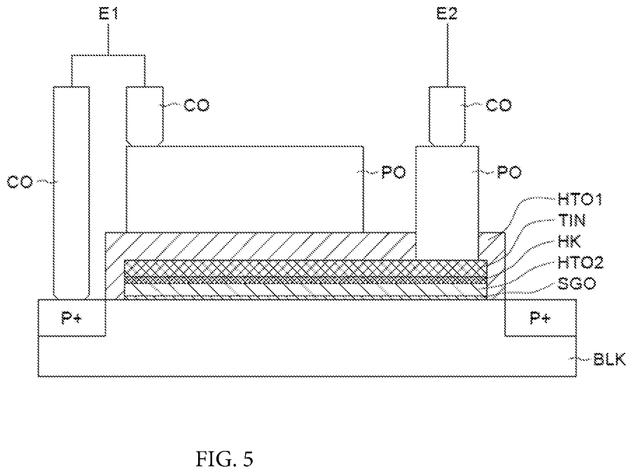

FIG. 5 illustrates the same structure as FIG. 4, but over a volume of the bulk semiconductor substrate BLK, instead of the semiconductor thin film of the SOI substrate.

Thus, the “MOS”-type second capacitive interface is made between the first armature TIN and the volume of the semiconductor substrate BLK.

The addition of the additional “MOS” capacitive element in parallel with the “MIM”-type capacitive element LCAP, as described with reference to FIGS. 4 and 5, allows increasing the surface capacitive value, but at the expense of the linearity of the capacitive value in the inversion and accumulation regimes.

1. An integrated circuit, comprising:
a region having a front face; and
at least one capacitive element including, over a surface at the front face, a stack of: a first conductive armature including a gate metal layer located over a layer of a material with a high dielectric constant forming a dielectric interface region over the first conductive armature; and a second conductive armature over the dielectric interface region.

2. The integrated circuit according to claim 1, wherein the gate metal layer includes a titanium nitride composition.

3. The integrated circuit according to claim 1, wherein the layer of the material with the high dielectric constant includes one of: a hafnium or zirconium oxide composition or a silicide composition.

4. The integrated circuit according to claim 1, wherein the second conductive armature includes a polycrystalline silicon composition.

5. The integrated circuit according to claim 1, wherein the first conductive armature includes an encapsulation polycrystalline silicon layer wrapping a top and side surfaces of the first conductive armature.

6. The integrated circuit according to claim 5, wherein the encapsulation polycrystalline silicon layer is in contact with a top surface of the gate metal layer.

7. The integrated circuit according to claim 1, further comprising a polycrystalline silicon local region in contact with a top surface of the gate metal layer and configured for ohmic coupling with a metallic contact.

8. The integrated circuit according to claim 1, further including at least one MOS transistor, wherein the at least one MOS transistor includes a gate region comprising a stack which has a formation identical to said second conductive armature over a formation of layers identical to said first conductive armature.

9. The integrated circuit according to claim 1, further including at least one high-voltage MOS transistor, wherein the at least one high-voltage MOS transistor includes a gate dielectric region comprising a formation identical to said dielectric interface region over the surface at the front face.

10. The integrated circuit according to claim 1, wherein said region comprises one of: a shallow isolation trench region; a region of a semiconductor thin film; or a bulk volume of a semiconductor substrate.

11. The integrated circuit according to claim 1. wherein said at least one capacitive clement further includes, between said surface at the front face and said layer of the material with the high dielectric constant, at least one gate dielectric layer.

12. A method for making at least one capacitive element in an integrated circuit, comprising:
manufacturing a first conductive armature at a front face of a region, comprising: forming a layer of a material with a high dielectric constant over a surface of said front face; and forming a gate metal layer over the layer of the material with the high dielectric constant;
manufacturing a dielectric interface region stacked over the first conductive armature; and
manufacturing a second conductive armature stacked over the dielectric interface region.

13. The method according to claim 12, wherein forming the gate metal layer includes forming a titanium nitride composition.

14. The method according to claim 12, wherein forming the layer of the material with a high dielectric constant comprises forming a hafnium or zirconium oxide composition or a silicide composition.

15. The method according to claim 12, wherein manufacturing the second conductive armature comprises forming a polycrystalline silicon composition.

16. The method according to claim 12, further comprising forming an encapsulation polycrystalline silicon layer wrapping a top and side surfaces of the first conductive armature.

17. The method according to claim 16, wherein said encapsulation polycrystalline silicon layer is in contact with a top surface of the gate metal layer.

18. The method according to claim 12, further comprising forming a polycrystalline silicon local region in contact with the gate metal layer and configured for ohmic coupling with a metallic contact.

19. The method according to claim 12, further including concomitantly making at least one MOS transistor and said at least one capacitive element, wherein manufacturing a gate region of the at least one MOS transistor comprises manufacturing layers identical to said manufacture of the first conductive armature, and a manufacture identical to said manufacture of the second conductive armature over said formation of layers.

20. The method according to claim 12, further including concomitantly making at least one high-voltage MOS transistor and said at least one capacitive element, wherein manufacturing a gate dielectric region of said least one high-voltage MOS transistor over the surface at the front face is identical to said manufacture of the dielectric interface region.

21. The method according to claim 12, wherein said region comprises one of: a shallow isolation trench region; a region of a semiconductor thin film; or a bulk region of a semiconductor substrate.

22. The method according to claim 12. wherein manufacturing the first conductive armature further includes forming at least one gate dielectric layer positioned between said surface of said front face and said layer of the material with the high dielectric constant.
